(19) United States
(12) Patent Application Publication
(10) Pub. No.: US 2025/0123321 A1
(43) Pub. Date: Apr. 17, 2025

(54) Optical Inspection Circuit and Method of Manufacturing an Optical Circuit Chip

(71) Applicant: Nippon Telegraph and Telephone Corporation, Tokyo (JP)

(72) Inventors: Yuichiro Ikuma, Musashino-shi, Tokyo (JP); Yusuke Nasu, Musashino-shi, Tokyo (JP); Kiyofumi Kikuchi, Musashino-shi, Tokyo (JP); Masayuki Takahashi, Musashino-shi, Tokyo (JP)

(21) Appl. No.: 18/688,534

(22) PCT Filed: Sep. 15, 2021
(86) PCT No.: PCT/JP2021/034002

§ 371 Date: Mar. 1, 2024

(51) Int. Cl. G01R 31/28; G02B 6/122; G02B 6/125; G02B 6/13

(52) U.S. Cl. CPC G01R 31/2851; G02B 6/1228; G02B 6/125; G02B 6/13

(57) ABSTRACT

The present invention is intended to provide an inspection optical circuit that can input and output inspection light to and from a circuit to be inspected with low loss, and can minimize a space for disposing the inspection optical circuit. Provided is an inspection optical circuit for inspecting a tested circuit formed on an optical circuit chip on a wafer by inputting and outputting light through a grating coupler, wherein the grating coupler is formed on the same optical circuit chip as the tested circuit, and a folded waveguide for connecting an input/output waveguide of the tested circuit and the grating coupler is formed in a region provided on a dicing line for cutting out the optical circuit chip.

### TECHNICAL FIELD

The present invention relates to an inspection optical circuit and a method for manufacturing an optical circuit chip, and more particularly relates to an inspection optical circuit for inspecting a tested circuit formed on an optical circuit chip on a wafer by inputting and outputting light, and a method for manufacturing an optical circuit chip including the inspection optical circuit.

### BACKGROUND ART

For increasing a communication capacity per device of optical communication devices, research and development have been actively promoted for more compact and highly functional optical modules. One of the promising technologies is silicon photonics (SiP). Silicon photonics is a technology of producing an optical circuit by a waveguide formed on a silicon-on-insulator (SOI) wafer and using silicon (Si) as a core material and silica glass (SiO₂) as a cladding material.

With silicon photonics, a plurality of optical circuits produced on a wafer is separated by dicing. An optical circuit chip is taken out and modularized together with other optical devices to produce an optical communication device such as an optical transmitter. In modularization, an optical fiber is connected to an input/output waveguide disposed on a chip end surface of the optical circuit chip, so that optical signals can be input and output.

In such a manufacturing process, if the measurement is performed for each chip after the optical circuit chips are cut out upon inspection of the characteristics of the optical circuit, it takes too much time, and the inspection cost increases. Therefore, the importance of wafer-level inspection (also referred to as on-wafer inspection) in which inspection is performed in a wafer state before dicing is increasing. It is common to arrange a grating coupler in the optical circuit chip, and an optical fiber is brought close to the grating coupler from an upper surface of the wafer to input and output light in wafer-level inspection. A large number of optical circuit chips are inspected at a high speed by wafer-level inspection to identify defective products and determine superiority/inferiority of characteristics, followed by dicing and modularization. In this way, optical communication devices with stable characteristics and high performance can be produced economically with high throughput.

For example, Patent Literature 1 discloses a configuration of an optical circuit capable of wafer-level inspection. An inspection optical circuit including a grating coupler is disposed adjacent to a circuit to be inspected on a wafer. On the end face of the circuit, a spot-size converter (SSC) is arranged for coupling the optical fiber with low loss. In the inspection circuit, the SSC for coupling inspection light to the SSC of the circuit is disposed with a groove serving as a dicing line interposed therebetween, thereby reducing excessive loss during inspection. In the conventional example, a space for placing the inspection circuit needs to be provided adjacent to the circuit. Accordingly, the degree of freedom is limited upon designing the optical circuit chip on the wafer.

### CITATION LIST

### Patent Literature

Patent Literature 1: Japanese Patent No. 6805111

### SUMMARY OF INVENTION

The present invention is intended to provide an inspection optical circuit that can input and output inspection light to and from a circuit to be inspected with low loss, and can minimize a space for disposing the inspection optical circuit, as well as a method for manufacturing an optical circuit chip including the inspection optical circuit.

To achieve the object above, according to one aspect of the present invention, provided is an inspection optical circuit for inspecting a tested circuit formed on an optical circuit chip on a wafer by inputting and outputting light through a grating coupler, wherein the grating coupler is formed on the same optical circuit chip as the tested circuit, and a folded waveguide for connecting an input/output waveguide of the tested circuit and the grating coupler is formed in a region provided on a dicing line for cutting out the optical circuit chip.

### BRIEF DESCRIPTION OF DRAWINGS

FIG. 1 is a diagram illustrating a configuration of an optical circuit chip according to a first embodiment of the present invention.

FIG. 2A is a view illustrating a cross-sectional structure of the optical circuit chip of the first embodiment.

FIG. 2B is a view illustrating a cross-sectional structure of the optical circuit chip of the first embodiment.

FIG. 2C is a view illustrating a cross-sectional structure of the optical circuit chip of the first embodiment.

FIG. 3 is a diagram illustrating a relationship between a connection loss with an optical fiber and a tip width of a tapered waveguide.

FIG. 4 is a diagram illustrating a configuration of an optical circuit chip according to a second embodiment of the present invention.

FIG. 5 is a diagram illustrating a cross-sectional structure of the optical circuit chip according to the second embodiment.

### DESCRIPTION OF EMBODIMENTS

A detailed description of embodiments of the present invention will be described below with reference to the drawings.

### First Embodiment

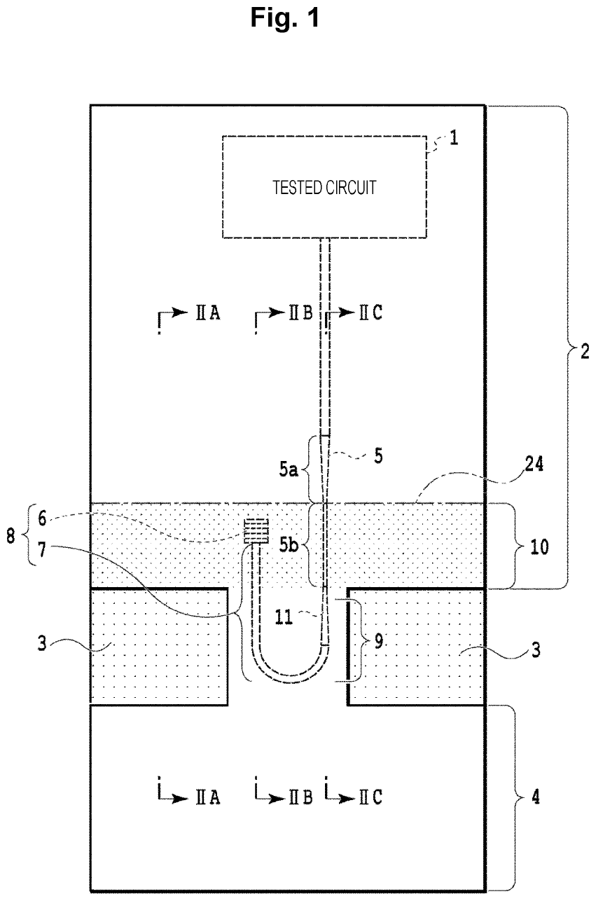

FIG. 1 illustrates a structure of an optical circuit chip according to a first embodiment of the present invention. It is a top view illustrating one of the optical circuit chips formed on the wafer and a portion of the periphery thereof, and showing a structure of a silicon (Si) core layer under the over-cladding layer in a transparent manner. An optical circuit chip 2 including a tested circuit 1 to be inspected and some of adjacent optical circuit chips 4 arranged with a deep groove 3 serving as a dicing line interposed therebetween illustrated. The optical circuit chip 2 and the optical circuit chip 4 are cut out from the wafer along the deep groove 3 by dicing after inspection. The tested circuit 1 formed on the optical circuit chip 2 on the wafer is inspected by inputting and outputting light through grating coupler 6 using the inspection optical circuit 8.

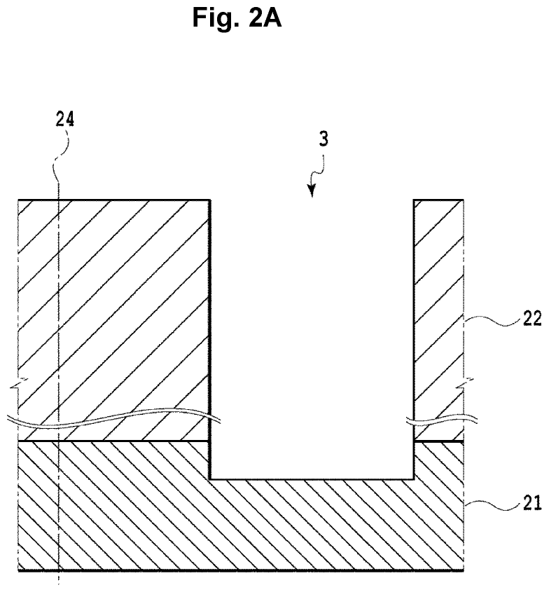

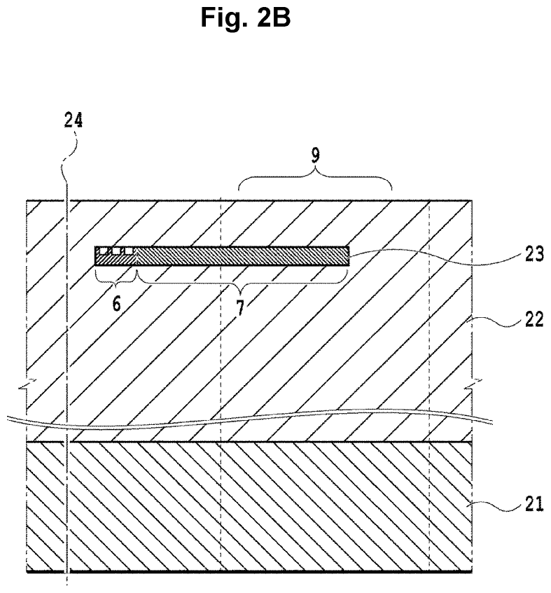

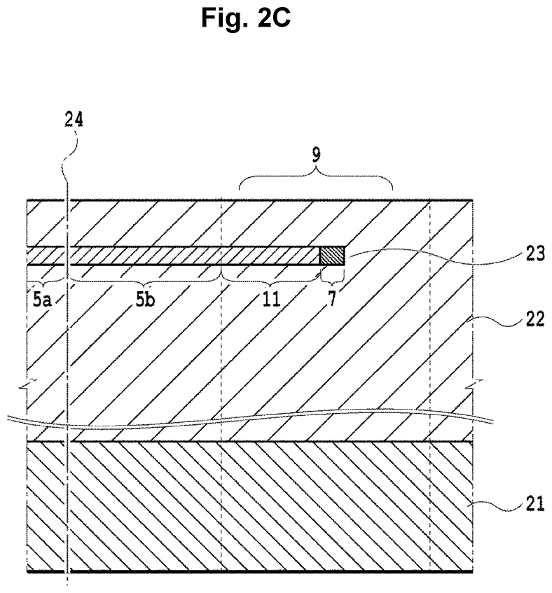

Each of FIGS. 2A-2C illustrates a cross-sectional structure of the optical circuit chip of the first embodiment. The optical circuits formed in the optical circuit chips 2 and 4 includes a silicon core layer 23 embedded in a cladding layer 22 made of SiO₂ formed on a silicon substrate 21. In the present embodiment, the deep groove 3 serving as a dicing line is a groove reaching the silicon substrate 21 from the upper surface of the wafer (FIG. 2A), but the depth of the dicing groove structure is not limited. It is not necessary to form a groove, and any configuration may be used as long as it can be identified as a dicing line. For example, a linear pattern may be formed by a silicon or metal film. The width of the dicing line through which a dicing blade passes is usually about 100 μm. The dicing line may be referred to as a scribe line.

For wafer-level inspection of the tested circuit 1 of the optical circuit chip 2, the inspection optical circuit 8 inputs the inspection light to an input waveguide of the tested circuit 1 or extracts the inspection light from an output waveguide of the tested circuit 1 via the grating coupler 6. In the optical circuit chip 2, the grating coupler 6 of the inspection optical circuit 8 and a part of the connecting waveguide 7 are formed (FIG. 2B).

The grating coupler 6 is an optical coupler for bringing an optical fiber close to the upper surface of the optical circuit chip 2 and inputting and outputting inspection light. The optical path converter may have any structure such as a mirror as long as light propagating through the waveguide formed in the optical circuit chip 2 can be emitted vertically or obliquely upward from the upper surface of the substrate.

The connecting waveguide 7 for connecting the grating coupler 6 and the tested circuit 1 has a folded waveguide, and is formed in a folded region 9 provided in the deep groove 3 (FIGS. 2B and 2C). As described above, the width of the dicing line, that is, the deep groove 3 is about 100 μm, which is about 1 order of magnitude larger than the minimum bending radius of the silicon waveguide. The folded region 9 is a region where the deep groove 3 is not dug, and also has an area sufficient for folding the folded waveguide of the connecting waveguide 7 (FIG. 1). The folded waveguide of the connecting waveguide 7 is coupled to the input/output waveguide via a connecting end surface to which the input/output waveguide of the tested circuit 1 and the optical fiber are connected.

After the optical circuit chip 2 is cut out from the wafer, a spot-size converter (SSC) 5 is disposed in contact with the connecting end face for connecting the input waveguide or the output waveguide of the tested circuit 1 and the optical fiber. When the SSC 5 is connected to the optical fiber on a polished surface 24, the SSC 5 expands a mode field diameter (MFD) of light to be optically coupled with low loss. Before the optical circuit chip 2 is cut out from the wafer, the SSC 5 also has a function of conversion into the MFD suitable for being connected to an SSC 11 provided in the folded waveguide of the connecting waveguide 7 at a position that will be a cut surface of the optical circuit chip 2 in subsequent processing.

The SSCs 5 and 11 each have a constant layer thickness in a stacking direction (FIG. 2C), and are implemented by a tapered waveguide (FIG. 1) that becomes thinner toward a chip end. This is because the MFD is expanded at a width not more than a certain width as the waveguide width is narrowed. In a case were the optical fiber and the SSC 11 are connected by the same MFD, the SSC 5 includes a tapered waveguide 5a and a thin-line waveguide 5b.

In a case where wafer-level inspection is performed, the optical fiber is brought close to the upper surface of the grating coupler 6 to input the inspection light. The input light is guided to the tested circuit 1 via the connecting waveguide 7, the SSC 11, and the SSC 5. The output light output from the tested circuit 1 propagates in a direction opposite to the inspection light and can be extracted from the grating coupler 6.

After the wafer-level inspection is completed, the optical circuit chip 2 and the optical circuit chip 4 are separated by dicing along the deep groove 3 which is a dicing line. At this time, the folded region 9 is removed by dicing. The cut surface of the optical circuit chip 2 is then polished to form the smooth connecting end surface (polished surface 24) suitable for optical fiber connection. In FIG. 1, a polished region 10 is a region to be polished and reduced, and has a width of 30 to 50 μm. The optical fiber is connected while facing the SSC 5 exposed at the end surface by polishing.

In the optical circuit chip 2, the vicinity of the cut surface on which the SSC 5 is formed includes the polished region 10 that disappears by polishing. Therefore, a region where a part of the tested circuit 1 is not formed is provided in a predetermined range from the cut surface. If the grating coupler 6 is disposed in this region, the design of the tested circuit 1 is not limited.

Since the folded region 9 and the polished region 10 disappear due to dicing and polishing, the entire inspection optical circuit 8 disappears. That is, the inspection optical circuit 8 can be configured only in the region that is finally unnecessary, and it is not necessary to secure a space for the inspection optical circuit 8 in other regions in addition to the adjacent optical circuit chip 4. Accordingly, not only the grating coupler 6 which is the optical path converter but also other elements necessary as the inspection optical circuit 8 may be disposed in the folded region 9 and the polished region 10.

Even if the grating coupler 6 remains in the optical circuit chip 2 after polishing, the characteristics of the tested circuit 1 are not affected. Therefore, if there is no restriction on the layout, a part of the inspection optical circuit 8 such as the optical path converter including the grating coupler 6 may be disposed outside the polished region 10.

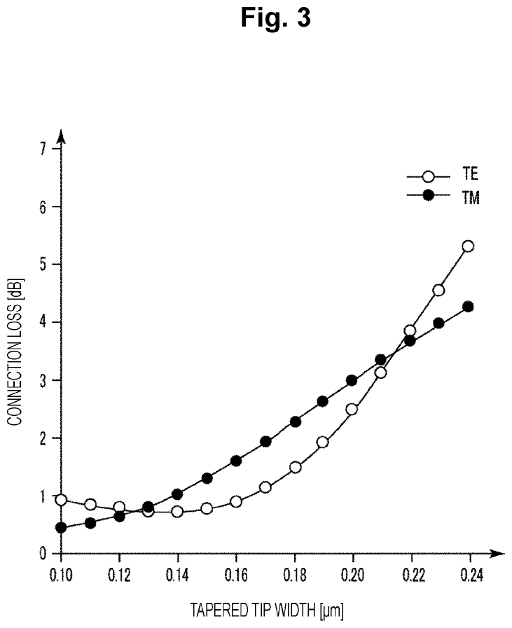

FIG. 3 illustrates the relationship between the connection loss with the optical fiber and the tip width of the tapered waveguide. A small-diameter core optical fiber having the MFD of 4 μm is assumed. When the tip width of the tapered waveguide 5a of the SSC 5 is 0.13 μm, it can be seen that the connection can be made with low loss of 0.77 dB in the TE-polarized wave and 0.84 dB in the TM-polarized wave.

The connecting waveguide 7 includes the folded waveguide and needs to be bent with a small radius. Since the effective refractive index of the TM-polarized wave is lower than that of the TE-polarized wave, the bending loss tends to be large. If the waveguide width is 0.3 μm and the bending radius is 20 μm, the bending loss at one folded position of 180° can be suppressed to a sufficiently low level of about 0.15 dB even for TM-polarized waves.

In a case where the optical fiber and the SSC 11 are connected by the same MFD, the tip width of the tapered waveguide 5a on the polished surface 24 is 0.13 μm, and the width of the thin-line waveguide 5b is also 0.13 μm. Since the width of the connecting waveguide 7 is 0.3 μm, if the connecting waveguide 7 is directly connected to the thin-line waveguide 5b, a loss occurs due to a difference in MFD. The connection loss is about 6.9 dB. In order to avoid this connection loss, the SSC 11 is installed in the connecting waveguide 7. The SSC 11 includes a tapered waveguide whose width continuously changes to 0.13 μm on a side connected to the thin-line waveguide 5b, that is, a position that will be the cut surface of the optical circuit chip 2 in the subsequent processing, and 0.3 μm on a side of the connecting waveguide 7.

If the lengths of the tapered waveguides 5a and the SSC 11 are too short, reflection and loss become large, and thus a certain length is required. When the length of the tapered waveguide having the width described above is 30 μm or more, both the loss and the reflection can be suppressed to a substantially negligible level.

Since the length of the SSC 11 is 30 μm and the bending radius of the connecting waveguide 7 is 20 μm, the length required for the connecting waveguide 7 to be folded back is 50 μm. Therefore, it is understood that the SSC 11 and the connecting waveguide 7 can be accommodated in the folded region 9 having a width of 100 μm with a margin.

According to the first embodiment, light can be input to and output from the tested circuit 1 with low loss, and the inspection optical circuit 8 can be compactly arranged without limiting the circuit design using dicing or polished regions.

### Second Embodiment

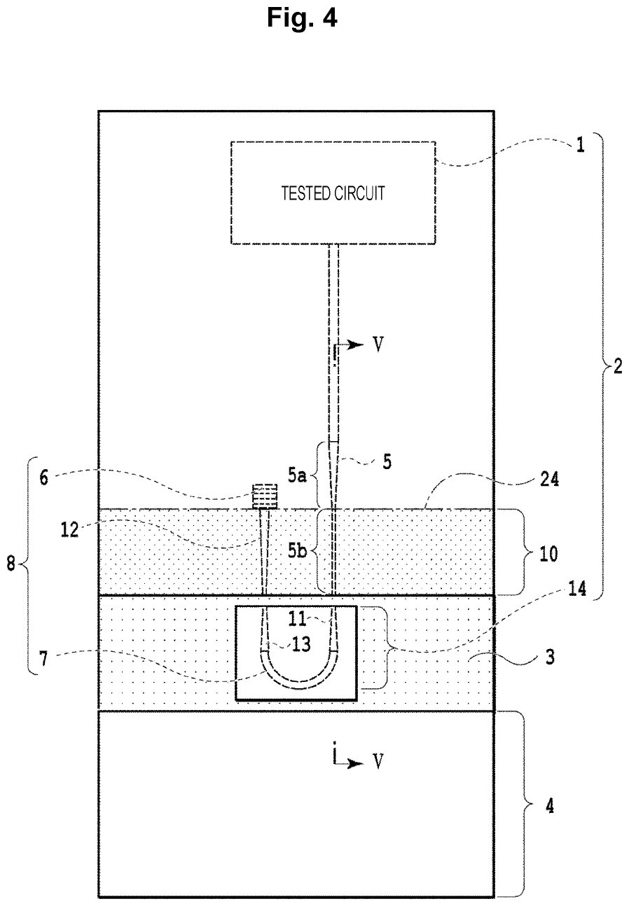

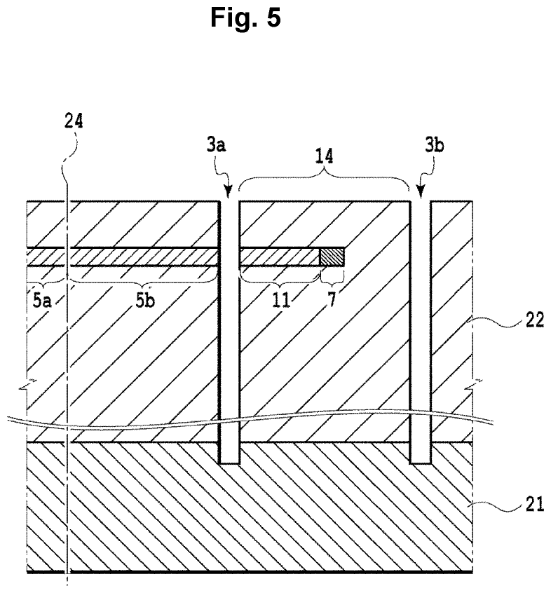

FIG. 4 illustrates a configuration of an optical circuit chip according to a second embodiment of the present invention, and FIG. 5 illustrates a cross-sectional structure of the optical circuit chip according to the second embodiment. The second embodiment is different from the first embodiment in that the folded region 9 is an island region 14 surrounded by the deep groove 3. That is, the island region 14 is separated from the cut surface of the optical circuit chip 2 and the cut surface of the optical circuit chip 4 by deep grooves 3a and 3b, respectively.

In the first embodiment, when the folded region 9 is removed by dicing, chipping (missing) may occur on the cut surfaces of the optical circuit chips 2 and 4, and the missing may extend to the inside of the optical circuit chip. Even if chipping occurs, there is no problem as long as the width of the polished region 10 is kept long and polishing is performed until a missing part is removed, but the polishing process takes a longer time. Therefore, by separating the folded region 9 from the optical circuit chips 2 and 4 and installing the folded region 9 as the island region 14, potential occurrence of chipping can be greatly suppressed.

By being separated by a groove, loss occurs due to radiation when light passes through such a portion. Assuming that the gap between the folded region 9 and the cut surfaces of the optical circuit chips 2 and 4 is 10 μm, the degree of loss will be described. First, the loss caused by the 10-μm gap between the SSC 5 and the SSC 11 is about 0.75 dB. Second, disconnection due to the deep groove 3 also occurs in the connecting waveguide 7 connected to the grating coupler 6. If the width of the connecting waveguide 7 is 0.3 μm and the MFD remains small, strong diffraction occurs and large loss occurs.

Therefore, the connecting waveguide 7 is newly provided with an SSC 12 on the side of the grating coupler 6, and the connecting waveguide 7 in the island region 14 is also newly provided with an SSC 13. Assuming that the tips of facing tapers of the SSC 12 and the SSC 13 are 0.13 μm, loss of about 0.75 dB occurs. Therefore, the sum of the loss between the SSC 5 and the SSC 11 is about 1.5 dB. That is, as compared with the first embodiment, the possibility that chipping occurs can be greatly reduced in exchange for slight loss increase of about 1.5 dB.

Although the embodiments of the present invention have been described above, it is within the scope of ordinary design change such as changing the material, obliquely arranging the waveguide to suppress the end surface reflection, or configuring by a method other than the tapered waveguide of the SSC, and the present invention is not limited thereto.

1. An inspection optical circuit for inspecting a tested circuit formed on an optical circuit chip on a wafer by inputting and outputting light through an optical path converter, wherein
the optical path converter is formed on the same optical circuit chip as the tested circuit, and
a folded waveguide for connecting an input/output waveguide of the tested circuit and the optical path converter is formed in a region provided on a dicing line for cutting out the optical circuit chip.

2. The inspection optical circuit according to claim 1, wherein the optical path converter is formed in a region to be polished and reduced by polishing after being cut off by dicing along the dicing line.

3. The inspection optical circuit according to claim 1, wherein the dicing line is a groove formed on the wafer, and the region is a region where the groove is not dug.

4. The inspection optical circuit according to claim 1, wherein the input/output waveguide of the tested circuit and the folded waveguide are connected via a spot-size converter including a tapered waveguide.

5. The inspection optical circuit according to claim 1, wherein the dicing line is a groove formed on the wafer, and the region is separated from the optical circuit chip by the groove.

6. A method for manufacturing a plurality of optical circuit chips including a tested circuit on a wafer, the method comprising:
forming an optical path converter on the same optical circuit chip as the tested circuit;
forming a folded waveguide for connecting an input/output waveguide of the tested circuit and the optical path converter in a region provided on a dicing line for cutting out the optical circuit chip; and
removing the region by dicing along the dicing line after the tested circuit is inspected.

7. The method according to claim 6, wherein the optical path converter is formed in a region to be polished and reduced by polishing after being cut off by dicing along the dicing line.

8. The method according to claim 6, wherein the dicing line is a groove formed on the wafer, and the region is a region where the groove is not dug.

9. The inspection optical circuit according to claim 2, wherein the dicing line is a groove formed on the wafer, and the region is a region where the groove is not dug.

10. The inspection optical circuit according to claim 2, wherein the input/output waveguide of the tested circuit and the folded waveguide are connected via a spot-size converter including a tapered waveguide.

11. The inspection optical circuit according to claim 3, wherein the input/output waveguide of the tested circuit and the folded waveguide are connected via a spot-size converter including a tapered waveguide.

12. The inspection optical circuit according to claim 9, wherein the input/output waveguide of the tested circuit and the folded waveguide are connected via a spot-size converter including a tapered waveguide.

13. The inspection optical circuit according to claim 2, wherein the dicing line is a groove formed on the wafer, and the region is separated from the optical circuit chip by the groove.

14. The method according to claim 7, wherein the dicing line is a groove formed on the wafer, and the region is a region where the groove is not dug.
